(19) United States
(12) Patent Application Publication
(10) Pub. No.: US 2008/0316068 A1
(43) Pub. Date: Dec. 25, 2008

(54) TEN MARK CODING SYSTEM AND ITS COMBINATING METHOD WITH A DATABASE AND ITS RETRIEVING METHOD

(76) Inventors: Chiu-Ching YAO, Mei He Tsun (TW); Pzu-Lung Yao, Mei He Tsun (TW)

Correspondence Address: SINORICA, LLC, 528 FALLSGROVE DRIVE, ROCKVILLE, MD, 20850, US

(21) Appl. No.: 11/767,416

(22) Filed: Jun. 22, 2007

(51) Int. Cl. H03M 11/00

(52) U.S. Cl. 341/28

(57) ABSTRACT

A Ten Mark coding system and its combination with a database and its retrieving method includes input-element electronic devices of numerals, English alphabets and mandarin phonetic symbols, and a database. The morphological components of Chinese characters are categorized into ten groups represented by numerals 0˜9, which are respectively provided with a group code and a numeral code, forming the very particular Ten Mark coding system stored in the database. The Ten Mark coding system can be used as an input method for retrieving Chinese characters, or combined with phonetic symbols to provide another input method. The input methods mentioned above can also be linked with other databases for retrieving data therein.

### BACKGROUND OF THE INVENTION

1. Field of Invention

This invention relates to an input and retrieve method for Chinese characters, particularly to one not only using numerals to code for Chinese characters and phrases and to be used as an input and retrieve method, but also linked with other databases to form a new retrieving method.

2. Description of the Related Art

With the popularity of the Internet, there are more and more works to be done depending on computerization. However, for Chinese characters, though there are many input methods used nowadays, they are not used as easily as English is. For example, the Chinese phonetic notations learned by most of Chinese does not require exploding words and memorizing regulations of code, but not only some notations of some Chinese characters are apt to be confused or used mistakenly, but also a lot of words have the same or almost the same notations so that the a user has to select the right one, thus actually delaying the key-in speed.

Although some input methods can improve key-in speed, they have to be practiced for quite a long time before used quickly and smoothly, and a user has to memorize particular ways of exploding words. For a beginner, it is a very inconvenient and tough job.

Moreover, the Chinese input methods used nowadays are unable to provide retrieval function after being linked with a database. That is, a proper retrieval system has to be prepared additionally if needed.

### SUMMARY OF THE INVENTION

The objective of this invention is not only to offer a system using numerals to code Chinese characters or phrases as to be used as an input and retrieve method, but also to link with other databases to become a new retrieving method.

The main characteristics of the invention are an input-element electronic device and a database. The input-element electronic device further includes input-element electronic devices of numerals, English alphabets and phonetic symbols.

The Ten Mark coding system includes a set of morphological component codes and a set of auxiliary codes. The morphological components of Chinese characters are categorized into ten groups represented by numerals 0˜9, which show respectively a morphological component, (referring to Attachment 1). Then all the numerals for the morphological components of a Chinese character can become a group code and a numeral code that represents that Chinese character, making up the very particular Ten Mark coding system, which can be stored in the database. The Ten Mark coding system can be used as an input method for retrieving Chinese characters, or combined with the phonetic notation system to provide another input method. The numeral codes in the database can be used as a text file and also as the input and retrieve method. In using, a user first has to analyze a Chinese character into plural morphological components respectively having a corresponding group code that also corresponds to a numeral code. The whole numeral codes are then keyed in via the numeral input-element electronic device to obtain the character.

The Ten Mark coding system can be combined with a phonetic notation system, such as roman phonetic symbols system or a mandarin (Chinese) phonetic symbols system to form a set of numeral-phonetic symbol codes and a set of phonetic notation-numeral codes, which are also altered to form a numeral notation-abbreviating method and a phonetic numeral-abbreviating method. Therefore, the coding methods mentioned above can be used as an input method and a retrieve method for Chinese characters, and linked with the database.

### BRIEF DESCRIPTION OF THE DRAWINGS

The above and other objects of the present invention will become readily apparent by reference to the following detailed description when considered in conjunction with the accompanying drawings wherein:

FIG. 1 is flow chart of a preferred embodiment of a Ten Mark coding system and its combination with a database and its retrieving method in the present invention;

Attachment 1 is a table of morphological components; and,

Attachment 2 is a table of auxiliary codes.

### DETAILED DESCRIPTION OF THE INVENTION

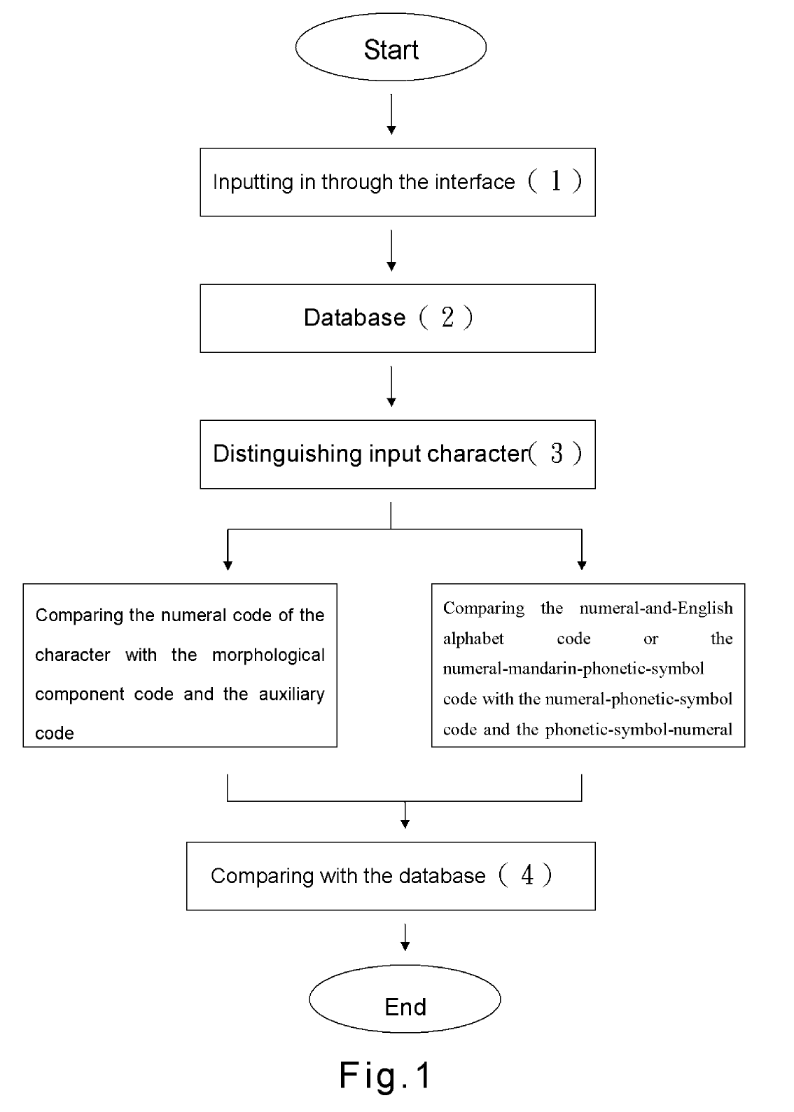

FIG. 1 is a flow chart of a preferred embodiment of Ten Mark coding system and its combination with a database and its retrieving method in the present invention, showing it being mainly composed of an input-element electronic device and a database. The input-element electronic device includes an input-element electronic device of numerals, English alphabets or phonetic notations. Through an input interface, a Chinese word can be keyed in by numeral codes, English alphabets or phonetic symbols to retrieve words from the database. The database includes a Ten Mark coding system that is provided with a set of morphological component codes, a set of auxiliary codes, a set of numeral codes representing phonetic symbols and a set of phonetic codes representing numerals. The morphological component codes and the auxiliary codes have corresponding group codes and numeral codes. When the database receives data keyed in, it is first to identify if the data are inputted through the numeral input-element electronic device or numeral-English input-element electronic device or numeral-phonetic symbol input-element electronic device. Then, the database is to compare it with the data and after confirmation to output a character or a phrase or a sentence keyed in by a user. The Ten Mark coding system uses ten numerals 0˜9 to code Chinese characters.

As Chinese characters are formed by a combination of different morphological components, the Ten Mark coding system particularly keeps all the morphological components categorized into 10 groups that are represented by Arabic numerals 0˜9 to form a group code and a numeral code to be stored in the database, as shown in FIG. 1. The numeral codes in the database can be induced as a text file and also used as an input method to retrieve Chinese characters. In using, a Chinese character is first exploded into several morphological components, and each morphological component corresponds to a group code that is corresponding to a numeral code, too. Next, find the group code for each of the morphological components and its corresponding numeral code. Then, key in the numeral codes through a numeral input-element electronic device to retrieve a character wanted.

For example, the Chinese character, [symbol] ,is coded and retrieved as follows.

[symbol]

(6) [symbol] (7) [symbol] (0)=670

Interpretation: (1) [symbol] are the morphological components forming the character of [symbol]
(2) 6, 7 and 0 are the group codes of the morphological components.
(3) 670 is the numeral code of the character [symbol]
   Therefore, if 6,7,0 are keyed in via the numeral input-element electronic device, the character [symbol] is obtained (retrieved).

In addition, the Ten Mark coding system can also be coded to retrieve a phrase or a sentence. That is, the group code of the first morphological component of each character in the phrase or the sentence is used as its code. In other words, the first morphological component of a word group is used as its group code that represents that phrase or sentence, so setting up the Ten Mark coding system by means of one character having only one code and then the all the codes are stored in the database that can function as a literature source bank. The usage of “one character one code” in the Ten Mark coding system is described as the following two examples.

[symbol]

= [symbol] (8) [symbol] (0) [symbol] (1) [symbol] (2)=8012

Interpretation: (1) [symbol] are the first morphological component of each character.
(2) 8, 0, 1, and 2 are their group codes.
(3) 8012 is its numeral code.

Therefore, as long as 8012 are keyed in, the phrase [symbol] is obtained.

[symbol]

= [symbol] (2) [symbol] (5) [symbol] (6) [symbol] (0)=2560

Interpretation: (1) [symbol] are the first morphological component of each character.
(2) 2, 5, 6 and 0 are their group codes.
(3) 2560 is its numeral code.
   Therefore, as long as 2, 5,6 and 0 are keyed in, the term [symbol] is obtained.

The Ten Mark coding system can also be combined with a phonetic symbol system such as the roman phonetic symbol system or the mandarin phonetic symbol system. That is, the numeral codes of the Ten Mark coding system is combined with phonetic symbols to form numeral-phonetic-symbol codes and phonetic-symbol-numeral codes, which can be altered into a numeral-phonetic-abbreviating method and a phonetic-numeral-abbreviating method. In the numeral-phonetic-abbreviating method, a character is first coded with the Ten Mark coding system into a numeral code and then added with the first phonetic symbol of the character for keying in. As for the phonetic-numeral-abbreviating method, the mandarin phonetic symbols of a character is first keyed in via the phonetic notation input element electronic device and then, added with the first numeral code of the character, or the roman phonetic symbol of the character is first keyed in and then, added with the first numeral code of the character. And, numeral-phonetic-abbreviating method and the phonetic-numeral-abbreviating method can also be linked to the database.

An example of the numeral-phonetic-abbreviating method is described below.

[symbol]

=four=4+

[symbol]

=five=5+

[symbol]

=four=4

Interpretation: (1). Four, five and four are the group codes of the character [symbol]
(2). 454 is its numeral code.
(3). [symbol] are the mandarin phonetic symbols of the character

[symbol]

Therefore, [symbol] 454 M [symbol] is the code for the character [symbol] . As long as 4, 5, 4 and [symbol] are keyed in and terminated by punching the space bar, the character [symbol] is immediately retrieved. [symbol] =four=4+ [symbol] =five=5+

[symbol]

=four=4

Interpretation: (1). Four, five and four are the group codes of the character [symbol]
(2). 454 is its numeral code.
(3). “Men” is the Roman phonetic symbols of

[symbol]

Therefore, [symbol] 454M [symbol] is the code for the character [symbol] As long as 4, 5, 4 and M are keyed in and terminated by punching the space bar, the character [symbol] is immediately obtained.

And, an example of the phonetic-numeral-abbreviating method is described below.

[symbol]

=

[symbol]

(6) [symbol] (7) [symbol] (0)=670=

[symbol]

6

Interpretation: [symbol] is the mandarin phonetic symbol of the character [symbol] and 6 (the first numeral code) is added to abbreviate the code.

Therefore, [symbol] 6 [symbol] is the code for the character [symbol] As long as [symbol] and 6 are keyed in and terminated by punching the space bar, the character [symbol] is immediately obtained.

[symbol]

=SH

= [symbol] (6) [symbol] (7) [symbol] (0)=670=

SH6

Interpretation: SH is the Roman phonetic symbol of the character [symbol] and 6 (the first numeral code) is added to abbreviate the code. Therefore, [symbol] SH6 [symbol] is the code for the character [symbol] As long as S, H and 6 are keyed in and terminated by punching the space bar, the character [symbol] is immediately obtained.

The Ten Mark coding system can not only be coded by combining numerals with phonetic symbols, but also be compatibly combined with the database of a library for Chinese books. The first group code of each character of a book name is combined together to become the book code. An example of how to code and retrieve a book name called [symbol] is described below.

Book name=

[symbol]

= [symbol] (8) [symbol] (0) [symbol] (1) [symbol] (2)=8012

Interpretation: (1) [symbol] are the first morphological component of each character of the book name.
(2) Eight, zero, one and two are their group codes.
(3) 8012 is the book code.
   Therefore, as long as 8012 are keyed in, the book name [symbol] is to be retrieved

Further, the Ten Mark coding system can be linked with the database of offices, institutions or schools to establish a “Ten Mark numeral personnel data file”, convenient to quickly provide correct personal information for emergent need, such as traffic accident, drowning or a fire. An example of a person called [symbol] is described below.

Name code: [symbol] (0) [symbol] (7) [symbol] (8)=087

Year of enrolment: 1979

Department: physics=03 (coded by school)

Sex: male=1

Blood type: o type=0

Therefore, the student card for [symbol] may be coded as follows.

087-79-03-1-0=087790310

Or 79-087-03-1-0=790870310

As long as the coded number is inputted in the Ten Mark coding system, the personal information for [symbol] can be obtained.

Further, the Ten Mark coding system may be linked with the database of a hospital to establish anamnesis code of patients. An example of a person called [symbol] is described below.

Name code: [symbol] (0) [symbol] (7) [symbol] (8)=087

Birthplace: [symbol] =915

Year & month of birth: 1976 [symbol] 08

[symbol]

Sex: male=1

Blood type: o type=0

Therefore, the anamnesis for [symbol] may be coded as follows.

087-915-76-08-1-0=087915760810

Or 078-76-08-1-0-915=078760810915

It is readily apparent that the above-described embodiments have the advantage of wide commercial utility. It should be understood that the specific form of the invention hereinabove described is intended to be representative only, as certain modifications within the scope of these teachings will be apparent to those skilled in the art. Accordingly, reference should be made to the following claims in determining the full scope of the invention.

What is claimed is:

1. A Ten Mark coding system and its combination with a database and its retrieving method executed by an electronic device with numeral input elements, said retrieving method comprising:
An initial input interface for inputting a Chinese character via a numeral input-element electronic device;
A database stored with information corresponding to morphological component codes and auxiliary codes;
A distinguishing input character to be identified whether said input character belongs to said morphological component code or said auxiliary code;
Comparing said input character with said morphological component codes or with said auxiliary codes stored in a database; and
retrieving a Chinese character or information from said database.

2. The Ten Mark coding system and its combination with a database and its retrieving method as claimed in claim 1, wherein said input interface is an English alphabet input-element electronic device and a mandarin phonetic symbol input-element electronic device.

3. The Ten Mark coding system and its combination with a database and its retrieving method as claimed in claim 1, wherein said morphological component code includes a group code and a numeral code.

4. The Ten Mark coding system and its combination with a database and its retrieving method as claimed in claim 1, wherein said auxiliary code includes a group code and a numeral code.

5. The Ten Mark coding system and its combination with a database and its retrieving method as claimed in claim 3, wherein said numeral code is combined with a phonetic symbol to form a numeral-phonetic-symbol code and a phonetic-symbol-numeral code.

6. The Ten Mark coding system and its combination with a database and its retrieving method as claimed in claim 5, wherein said numeral-phonetic-symbol code and said phonetic-symbol-numeral code are stored in said database for comparing with an input character.

7. The Ten Mark coding system and its combination with a database and its retrieving method as claimed in claims 1, wherein numerals 0˜9 are used to correspond to said morphological component codes, and all of said morphological components of Chinese characters are categorized with said numerals 0˜9 so as to obtain said group code and said numeral code.

8. The Ten Mark coding system and its combination with a database and its retrieving method as claimed in claim 7, wherein said Chinese characters include those of traditional Chinese characters and simplified Chinese characters and Japanese kanji.

9. The Ten Mark coding system and its combination with a database and its retrieving method as claimed in claim 5, wherein said phonetic symbols includes roman phonetic symbols and mandarin phonetic symbols.
